(19) United States
(12) Patent Application Publication
(10) Pub. No.: US 2026/0059870 A1
(43) Pub. Date: Feb. 26, 2026

(54) MULTI-DIE CMOS IMAGE SENSOR INTEGRATED CIRCUIT DEVICE WITH FRONTSIDE-BASED ISOLATION STRUCTURE

(71) Applicant: Taiwan Semiconductor Manufacturing Company, Ltd., Hsinchu (TW)

(72) Inventors: Chun-Hao Chuang, Hsinchu City (TW); Keng-Yu Chou, Kaohsiung City (TW); Cheng-Yu Huang, Hsinchu (TW); Wen-Hau Wu, New Taipei City (TW); Wei-Chieh Chiang, Yuanlin Township (TW); Chih-Kung Chang, Zhudong Township (TW)

(21) Appl. No.: 18/814,937

(22) Filed: Aug. 26, 2024

(51) Int. Cl. H01L 27/146

(52) U.S. Cl. CPC H10F 39/18; H10F 39/014; H10F 39/8037; H10F 39/807; H10F 39/811

(57) ABSTRACT

Some embodiments relate to an integrated circuit device having an IC layer including a plurality of pixel cell groups. Each pixel cell group includes a plurality of pixel cells arranged in a 2-by-2 configuration. Each pixel cell includes a photodetector in a substrate, and a transfer transistor electrically coupled to the photodetector and configured to transfer electrical charge collected at the photodetector across a first surface of the substrate. The IC layer further includes at least one dielectric structure extending from the first surface to a second surface of the substrate and separating each pixel cell from neighboring pixel cells. The dielectric structure includes a first gap disposed at a common corner of the pixel cells. A conductive structure is electrically connected to at least one of the photodetector or the transfer transistor of each of the pixel cells and is disposed in the first gap over the first surface.

### BACKGROUND

Use of a complementary metal-oxide-semiconductor (CMOS) image sensor (CIS) in an electronic device often involves the utilization of various additional circuit resources to render useful the signals generated by the CIS. For example, in addition to a pixel array for receiving light, the CIS may be accompanied by one or more of timing circuitry for measuring an amount of the received light, image processing circuitry to generate the resulting image data, memory for storing the image data, and so on. Such circuits may be incorporated within a single CIS integrated circuit (IC) device to reduce the footprint consumed by the device on a printed circuit board (PCB).

Additionally, separation or isolation structures may positioned between adjacent pixels of the pixel array to limit both the amount of properly received light that escapes from a pixel and/or the amount of unwanted light (e.g., from a neighboring pixel) that enters the pixel. Such structures may also serve as electrical isolation structures, thus potentially reducing optical and electrical crosstalk between pixels and limiting overall electrical noise in the produced image signals.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a schematic exploded isometric view of some embodiments of a CIS multi-die (e.g., multi-layer) IC device, according to the present disclosure.

FIG. 2A illustrates a block diagram of some embodiments of a pixel cell employable in a CIS multi-layer IC device, according to the present disclosure.

FIG. 2B illustrates a schematic diagram of some embodiments of a pixel cell employable in a CIS multi-layer IC device, according to the present disclosure.

FIG. 3 illustrates a schematic/block diagram of some embodiments of a pixel cell, a per-pixel circuit, an in-pixel circuit, and an application-specific integrated circuit (ASIC) employable in a multi-layer CIS IC device, according to the present disclosure.

FIG. 4 illustrates a block diagram of some embodiments of a multi-layer CIS IC device, according to the present disclosure.

FIGS. 5A and 5B illustrate cross-sectional and plan views, respectively, of some embodiments of a multi-layer CIS IC device employing a frontside-based isolation structure, according to the present disclosure.

FIGS. 6A and 6B illustrate cross-sectional and plan views, respectively, of some embodiments of another multi-layer CIS IC device employing a frontside-based isolation structure, according to the present disclosure.

FIGS. 7A and 7B illustrate cross-sectional and plan views, respectively, of some embodiments of another multi-layer CIS IC device employing a frontside-based isolation structure, according to the present disclosure.

FIGS. 8A and 8B illustrate cross-sectional and plan views, respectively, of some embodiments of another multi-layer CIS IC device employing a frontside-based isolation structure, according to the present disclosure.

FIGS. 9A and 9B illustrate plan views of some embodiments of multiple pixel cell groups of a multi-layer CIS IC device employing a frontside-based isolation structure, according to the present disclosure.

FIGS. 10A through 10L illustrate cross-sectional side views of some embodiments of a CIS multi-die IC device employing a frontside-based isolation structure at various stages of manufacture, according to the present disclosure.

FIG. 11 illustrates a methodology of forming a CIS multi-die IC device employing a frontside-based isolation structure, in accordance with some embodiments.

### DETAILED DESCRIPTION

The present disclosure provides many different embodiments, or examples, for implementing different features of this disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In a complementary metal-oxide-semiconductor (CMOS) image sensor (CIS), incorporation of isolation structures (e.g., for optical and/or electrical isolation purposes) and accompanying electrical circuits (e.g., for image signal generation, storage, and processing) associated with each pixel of a pixel array into a single integrated circuit (IC) device may become more difficult in view of an increasing demand for higher image resolution and thus smaller pixel sizes. More specifically, the smaller an overall pixel size, the less area that is available (e.g., in a plan view) for the detection and measurement of received light, as well as for the optical and electrical isolation structures associated therewith.

To address these issues, the present disclosure provides some embodiments of a multi-die CIS IC device with a frontside-based isolation structure. In some embodiments, a layer or die of the IC device may include a plurality of cell groups, where each cell group includes a plurality of (e.g., four) pixel cells (e.g., arranged in a 2-by-2 (e.g., two rows by two columns) in a plan view). Each of the pixel cells may include a photodetector in a substrate of the IC layer and a transfer transistor electrically coupled to the photodetector. In some embodiments, the transfer transistor may be configured to transfer electrical charge collected at the photodetector across a first surface (e.g., a frontside surface) of the substrate.

The IC layer may also include at least one dielectric structure (e.g., a frontside deep trench isolation (DTI) structure) that extends from the first surface to a second surface of the substrate and separates each of the pixel cells from neighboring pixel cells. Further, in some embodiments, the at least one dielectric structure may include a gap at a common corner of the plurality of pixel cells (e.g., at or near a central region of the 2-by-2 configuration). A conductive structure may be electrically connected to at least one of the photodetector or the transfer transistor of each of the pixel cells and may be disposed in the gap over the first surface of the substrate.

Accordingly, use of some embodiments may provide a CIS IC device by which isolation between pixel cells is achieved by a single layer of dielectric structure that is created from a side (e.g., a frontside) of a substrate opposite the side at which the image light is to be received. As a result, better overlay (e.g., lateral) alignment may occur between the dielectric structure and various features of the IC layer proximate the frontside (e.g., floating diffusion (FD) nodes associated with the transfer transistors). Such improved alignment may facilitate an increased area for device layout and a concomitant reduction in the overall area of the pixel cells, possibly leading to an increase in image resolution.

Further, formation of the at least one dielectric structure may occur relatively early in the overall CIS IC fabrication process. Under some circumstances, formation of such an isolation structure across the depth of the substrate may disrupt molecular (e.g., silicon-silicon) bonds, possibly resulting in structural defects around a sidewall of the one or more trenches in which the dielectric structure resides. Such defects may cause current leakage and thus adversely affect dark pixel key performance indicators (KPIs). However, as the dielectric structure may be formed early in the fabrication process, heating produced by subsequent process steps may facilitate compensation of such defects.

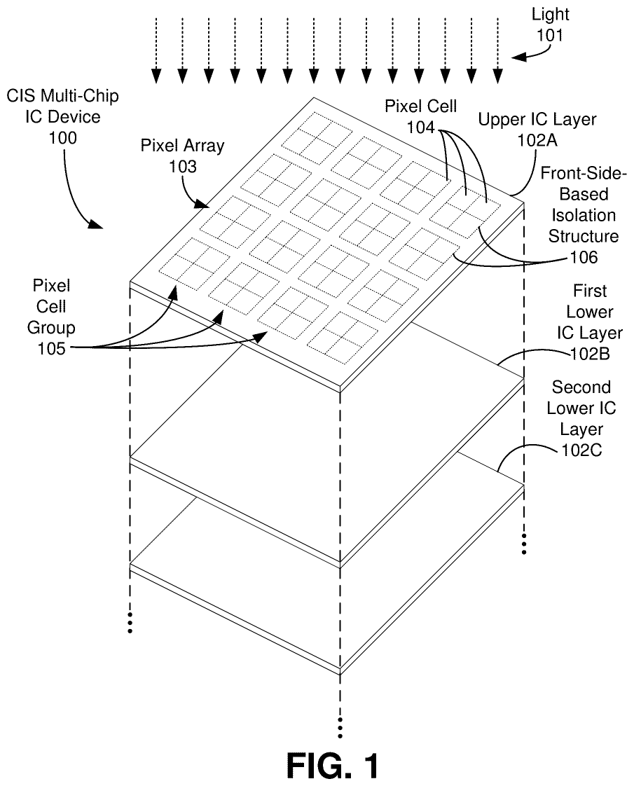

FIG. 1 illustrates a schematic exploded isometric view of some embodiments of a CIS multi-die IC device 100, according to the present disclosure. CIS multi-die IC device 100 (also referred to as CIS IC device 100 below) includes an upper IC die or layer 102A and one or more lower IC layers 102B and 102C that are bonded together. In some embodiments, upper IC layer 102A and lower IC layers 102B and 102C (e.g., first lower IC layer 102B, second lower IC layer, and so on) are bonded at the wafer level (e.g., prior to singulation into individual ICs). In other embodiments, one or more of upper IC layer 102A and lower IC layers 102B and 102C are bonded to each other according to die-to-wafer or flip chip bonding.

In some embodiments, upper IC layer 102A includes a pixel array 103 that includes a plurality of pixel cells 104 organized as a plurality of pixel cell groups 105. Each pixel cell 104 is sensitive to light 101 impacting an upper surface (e.g., a backside surface) of upper IC layer 102A. Further, in some embodiments, as described in greater detail below, upper IC layer 102A may include additional circuitry that may be incorporated with pixel cells 104. Additionally, one or more lower IC layers 102B and 102C may include processing circuits (not shown in FIG. 1) that may be collectively employed (e.g., to generate image data representing light 101 received at pixel cells 104). In some embodiments, by organizing pixel cells 104 and other circuitry among the different IC layers 102A-102C as described below, each such IC layer may be constructed using a fabrication process or technology node that is appropriate for the associated circuitry.

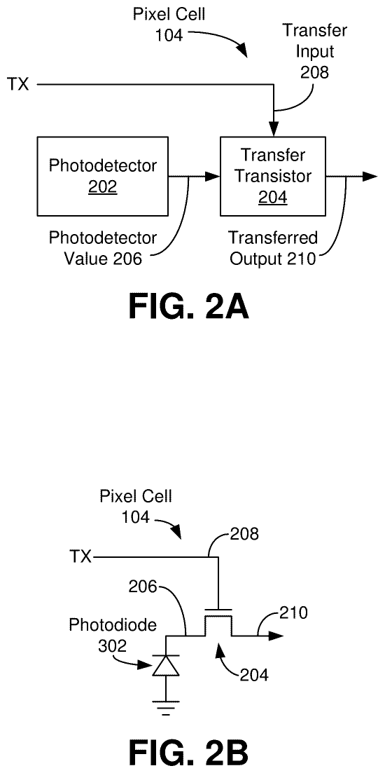

FIG. 2A illustrates a block diagram of some embodiments of pixel cell 104 employable in CIS multi-die IC device 100, according to the present disclosure. In such embodiments, pixel cell 104 may include a photodetector 202 that provides a photodetector value 206 (e.g., an amount of electrical charge) and a transfer transistor 204 that forwards the value as a transferred output 210 under the control of a transfer input 208. In some embodiments, and as described below, photodetector 202 may include a photodiode 302, such as a PIN diode or pinned photodiode (PPD). However, in other embodiments, photodetector 202 may be a phototransistor or other type of photodetector. In some embodiments, pixel cells 104 may be apportioned to detect different wavelength ranges (e.g., grouped as red, blue, and green pixels) by being associated with corresponding color filters positioned over upper IC layer 102A of FIG. 1. Also, while photodetector 202 may be sensitive to a particular visible band or range, or set of ranges, of visible light, photodetector 202 may be sensitive to non-visible light (e.g., infrared light) in other embodiments.

FIG. 2B illustrates a schematic diagram of some embodiments of pixel cell 104 employable in CIS multi-die IC device 100, according to the present disclosure. As depicted in FIG. 2B, pixel cell 104 may include a photodiode 302 with a grounded (e.g., connected to a source voltage VSS) anode and a cathode providing photodetector value 206 to a first source/drain connection of transfer transistor 204. Further, transfer transistor 204 may transfer photodetector value 206 to transferred output 210 at a second source/drain region in response to a transfer input 208 (also marked as “TX” in FIG. 2B) at a gate input of transfer transistor 204. However, other configurations for photodetector 202 and transfer transistor 204 of FIG. 2A may be employed in other embodiments.

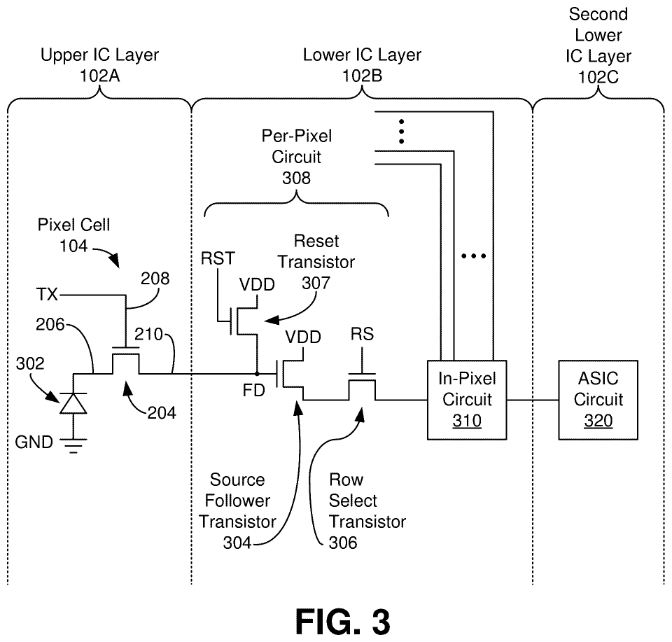

FIG. 3 illustrates embodiments in which pixel cell 104 and associated processing circuits may be organized or apportioned among three IC layers of a CIS IC device (e.g., to facilitate improved device performance and/or cost). More specifically, FIG. 3 illustrates a schematic/block diagram of some embodiments of pixel cell 104, a per-pixel circuit 308, an in-pixel circuit 310, and an application-specific integrated circuit (ASIC) 320 employable in a three-layer CIS multi-die IC device, according to the present disclosure. As shown, pixel cells 104, including a photodetector (e.g., photodiode 302) and transfer transistor 204, as described above, are included in upper IC layer 102A. Further, per-pixel circuit 308 and in-pixel circuit 310 are located on first lower layer IC layer 102B, and ASIC circuit 320 is positioned on second lower IC layer 102C.

While a single pixel cell 104 and a single per-pixel circuit 308 are depicted in FIG. 3, at least some embodiments described herein include a plurality of pixel cells 104 (e.g., organized into pixel cell groups 105 that may include rows and columns of pixel cells 104, as depicted in FIG. 1) and a plurality of per-pixel circuits 308, where each per-pixel circuit 308 is electrically coupled to a corresponding one of pixel cells 104. As also shown in FIGS. 3, each of the per-pixel circuits 308 may be coupled to in-pixel circuit 310.

In some embodiments, per-pixel circuit 308 is configured to provide a timed indication of the electrical charge (e.g., transferred output 210) transferred from photodiode 302 via transfer transistor 204 for a corresponding pixel cell 104. For example, in some embodiments, per-pixel circuit 308 may include a source follower transistor 304, a row select transistor 306, and/or a reset transistor 307. Source follower transistor 304 may be electrically coupled to transfer transistor 204 (e.g., at a gate connection of source follower transistor 304) and configured to buffer transfer transistor 204 (e.g., transferred output 210) from another circuit (e.g., within in-pixel circuit 310, such as a column bus). In some embodiments, source follower transistor 304 may be configured as an amplifier for transferred output 210. In some examples, the gate connection to source follower transistor 304 may be viewed as a floating diffusion (marked “FD” in FIG. 3) at which electrical charge is provided prior to being transferred to in-pixel circuit 310.

Reset transistor 307 may also be coupled to source follower transistor 304 (e.g., at a gate connection of source follower transistor 304) to reset the electrical charge being transferred from photodiode 302 by transfer transistor 204 under the control of a reset (“RST”) signal (e.g., by raising the gate connection of source follower transistor to a drain (supply) voltage VDD).

In some embodiments, row select transistor 306 may be configured to forward the electrical charge of pixel cell 104 via source follower transistor 304 to in-pixel circuit 310 in a timed manner based on a row select (“RS”) signal (e.g., driving a gate connection of row select transistor 306). Also, in some embodiments, row select transistor 306, by way of drain/source connections, may couple source follower transistor 304 to a column bus of in-pixel circuit 310.

In-pixel circuit 310, in some embodiments, may process the plurality of timed indications of electrical charge received by source follower transistor 304 (e.g., for multiple columns of pixel cells 104 on a row-by-row basis) to at least partially generate analog image data represented by the electrical charges stored in pixel cells 104. In some embodiments, in-pixel circuit 310 may generate the signals (e.g., TX, RST, and RS signals) controlling pixel cell 104 and per-pixel circuit 308, as described above. More broadly, in some embodiments, in-pixel circuit 310 may include one or more of column-level circuitry, column bus signal lines (e.g., one signal line per column), one or more bias transistors (e.g., to bias a voltage level of one or more column bus signal lines), a column controller, and a row controller.

ASIC circuit 320, in some embodiments, may include any additional circuitry (e.g., one or more analog-to-digital (ADC) converters, memory, image signal processors (ISPs), communications circuitry, power circuitry, and/or the like) that may be employed as part of, or in connection with, CIS IC device 100.

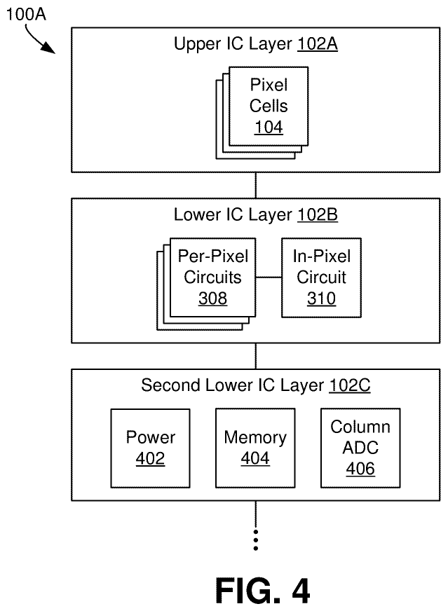

FIG. 4 illustrates a block diagram of some embodiments of a multi-layer CIS multi-die IC device 100A, according to the present disclosure. For example, in FIG. 4, CIS IC device 100A includes upper IC layer 102A that includes pixel cells 104 and further includes first lower IC layer 102B that includes per-pixel circuits 308 and in-pixel circuit 310 (e.g., as discussed above in connection with FIG. 3). Additionally, in some embodiments, CIS IC device 100A also includes second lower IC layer 102C that may include power circuitry 402 (e.g., to provide, filter, and/or distribute power for CIS IC device 100A), one or more memories 404 (e.g., to store digital image data represented in pixel cells 104), and/or column ADCs 406 (to convert the timed indications for the electrical charges of pixel cells 104 to digital image data for each column of pixel cells 104). In some embodiments, additional lower IC layers (not explicitly shown in FIG. 4) may be included in CIS IC device 100A that incorporate additional circuits, such as a phased-lock loop (PLL) (e.g., to generate timing signals for in-pixel circuit 310 and other portions of CIS IC device 100A), an Inter-Integrated Circuit (I2C) (e.g., for providing communication between CIS IC device 100A and other circuits or systems), and an ISP (e.g., for processing digital image data generated from the electrical charges in pixel cells 104).

In some embodiments, the partitioning of the above-described functions among the upper IC layer 102A and the various lower IC layers 102B, 102C, and so on may simplify fabrication of each separate IC layer 102A-102C by reducing the number of different process technologies that are required to generate each separate one of the IC layers. For example, in FIG. 4, upper IC layer 102A may be fabricated using at least a specialized process directed to creating pixel cells 104 (e.g., to minimize the footprint of each pixel cell 104). Further, in some embodiments, first lower IC layer 102B may be fabricated using at least a low-power technology node (e.g., to implement per-pixel circuits 308 and in-pixel circuit 310). In some embodiments, second lower IC layer 102C may be implemented using at least a high-voltage (e.g., thick oxide) technology (e.g., to accommodate the relatively high-level voltages of power circuitry 402 and/or column ADCs 406). In some embodiments, more than one technology node may be employed on one or more IC layers 102A-102C. However, employing more than one IC layer may aid in preventing the use of three or more process technology nodes on any single IC layer.

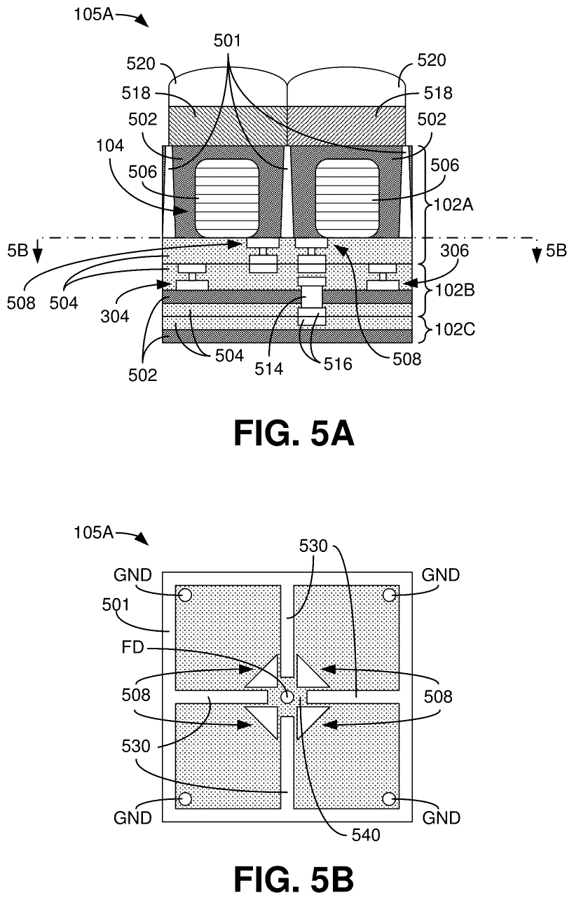

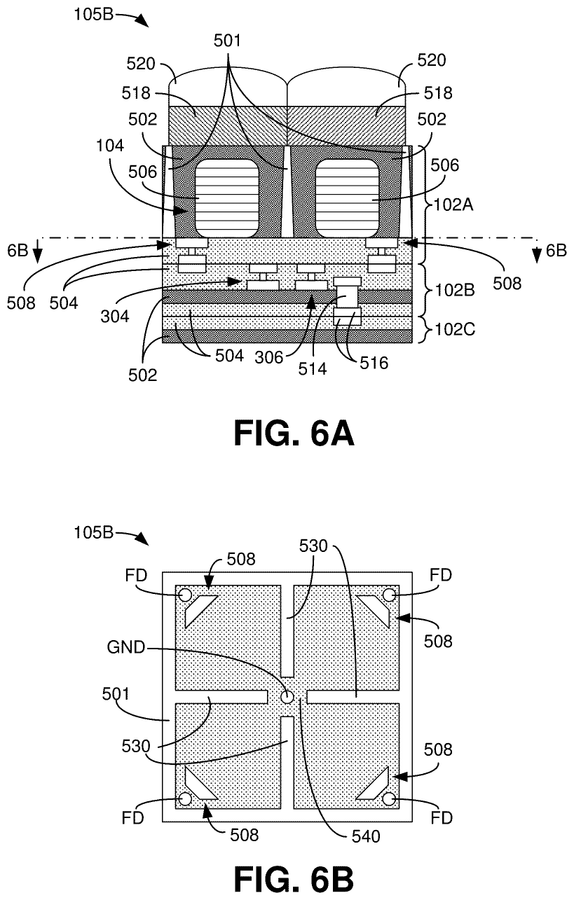

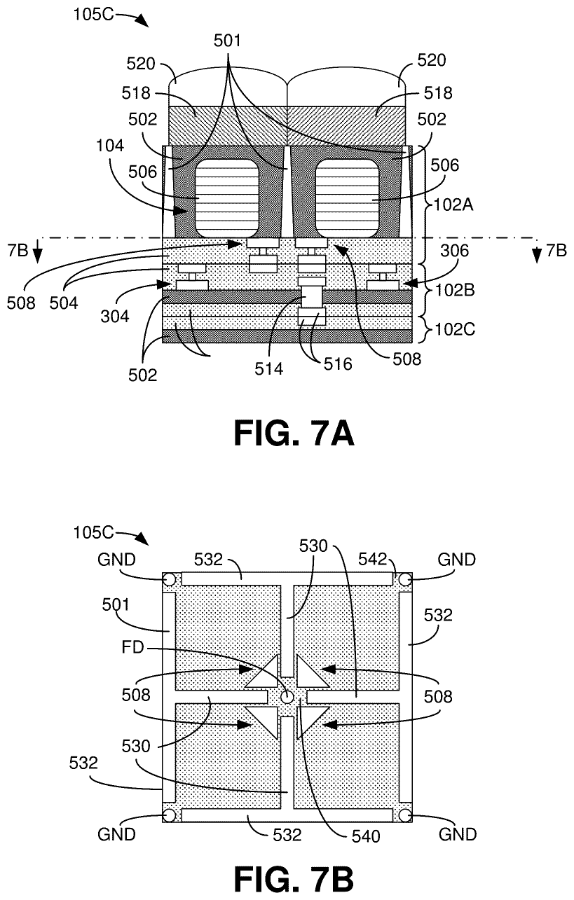

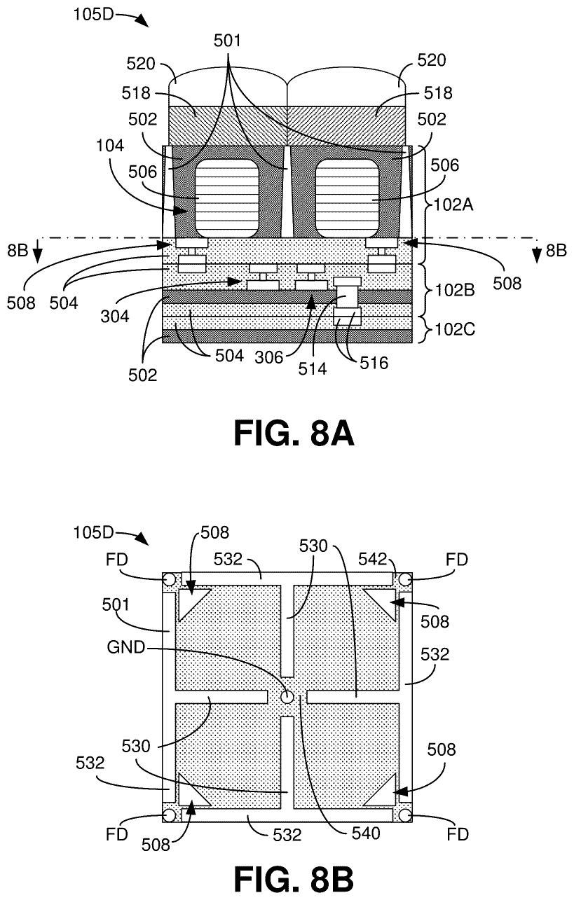

Each pair of FIGS. 5A and 5B, FIGS. 6A and 6B, FIGS. 7A and 7B, and FIGS. 8A and 8B illustrate cross-sectional and plan views, respectively, of some embodiments of a multi-layer CIS IC device employing a frontside-based isolation structure, according to the present disclosure. More specifically, FIGS. 5A and 5B depict a pixel cell group 105A, FIGS. 6A and 6B depict a pixel cell group 105B, FIGS. 7A and 7B depict a pixel cell group 105C, and FIGS. 8A and 8B depict a pixel cell group 105D. Further, each of the above pairs of figures depicts a single pixel cell group 105 in an upper IC layer 102A that includes a 2-by-2 configuration of four pixel cells 104. Also shown in FIGS. 5A, 6A, 7A, and 8A are portions of first lower IC layer 102B and second lower IC layer 102C.

Further illustrated in FIGS. 5A, 6A, 7A, and 8A are lenses (e.g., microlenses) 520 and filters 518, where one lens 520 and one associated filter 518 may be disposed over a corresponding pixel cell 104 to focus and subsequently filter light provided to pixel cell 104. In some embodiments, each pixel cell group 105 may include filters of different colors (e.g., red, green, and blue). Further, in some embodiments, one or more pixel cell groups 105 may include one red, two green, and one blue filter. However, other combinations of colors or wavelength bands may be associated with filters 518 in other embodiments.

In each of FIGS. 5A, 6A, 7A, and 8A, upper IC layer 102A may include a substrate 502 and a dielectric layer 504. In some embodiments, substrate 502 of upper IC layer 102A, as well as substrate 502 of first lower IC layer 102B and/or second lower IC layer 102C, may be a semiconductor substrate that may include silicon (Si) and/or another semiconductor material. Further, in some embodiments, dielectric layer 504 of upper IC layer 102A, as well as dielectric layer 504 of first lower IC layer 102B and/or second lower IC layer 102C, may include one or more dielectric materials, including, but not limited to, silicon oxide (SiOₓ) (e.g., silicon dioxide (SiO₂)), silicon nitride (SiN), silicon carbide (SiC), carbon doped silicon dioxide, silicon oxynitride, borosilicate glass (BSG), phosphorus silicate glass (PSG), borophosphosilicate glass (BPSG), fluorosilicate glass (FSG), undoped silicate glass (USG), a porous dielectric material, or the like.

Regarding these same figures, substrate 502 of upper IC layer 102A may include a photosensitive region 506 for each pixel cell 104. Each photosensitive region 506 may form a corresponding photodetector (e.g., photodiode 302 of FIG. 3) with the surrounding regions of substrate 502. In some embodiments, photosensitive regions 506 are formed proximate a lower surface (e.g., a frontside surface) of substrate 502 adjacent to which dielectric layer 504 of upper IC layer 102A is disposed. Further, in some embodiments, within dielectric layer 504 proximate the lower surface of substrate 502, a transfer transistor 508 (e.g., including at least one source/drain connection, a gate oxide material with a connecting metal contact, and possibly a spacer structure) may be coupled with each photosensitive region 506 to form a corresponding pixel cell 104.

In some embodiments, dielectric layer 504 of upper IC layer 102A may include a plurality of conductive structures at a lower surface of dielectric layer 504 opposite substrate 502. Further, dielectric layer 504 of upper IC layer 102A may include conductive structures electrically connecting pixel cells 104 to the conductive structures of upper IC layer 102A. In some embodiments, the conductive structures may include conductive (e.g., metal) layers interconnected with conductive (e.g., metal) vias. Also, in some embodiments, the conductive pads may include metal (e.g., copper, aluminum, or the like) or another conductive material.

Further, in some embodiments, as described in greater detail below, at least one dielectric structure 501 is disposed within upper IC layer 102A to at least partially isolate each pixel cell 104 from other pixel cells 104, and possibly from other portions of upper IC layer 102A.

First lower IC layer 102B, in turn, may include its own substrate 502 (e.g., a silicon substrate) and two dielectric layers 504. Within first lower IC layer 102B, substrate 502 may include at least a portion of a first processing circuit (e.g., plurality of per-pixel circuits 308 of FIG. 3, such as source follower transistor 304 and/or row select transistor 306). At an upper surface of a first dielectric layer 504 of first lower IC layer 102B proximate a lower surface of dielectric layer 504 of upper IC layer 102A may be a plurality of conductive structures, where each of conductive structures of first dielectric layer 504 of first lower IC layer 102B is in direct contact with a corresponding conductive structure of dielectric layer 504 of upper IC layer 102A. Also, conductive structures (e.g., vias) may be disposed within first dielectric layer 504 of first lower IC layer 102B to electrically couple the conductive structures of first dielectric layer 504 with the per-pixel circuits 308 of FIG. 3 (e.g., source follower transistor 304 and/or row select transistor 306).

Disposed at a lower surface of substrate 502 of first lower IC layer 102B is second dielectric layer 504 of first lower IC layer 102B. At a lower surface of second dielectric layer 504 is disposed a plurality of conductive structures 516. In some embodiments, one or more through-substrate vias (TSVs) 514 may be disposed in substrate 502 of first lower IC layer 102B and into first dielectric layer 504 to electrically couple conductive structure 516 of first dielectric layer 504 with conductive structures 516 of second dielectric layer 504 of first lower IC layer 102B.

As also shown in FIGS. 5A, 6A, 7A, and 8A, second lower IC layer 102C may include a substrate 502 and a dielectric layer 504. Second lower IC layer 102C may include ASIC circuit 320, as shown in FIG. 3, but is not explicitly depicted in FIGS. 5A, 6A, 7A, and 8A to simplify those figures.

In some embodiments, some circuits in substrates 502 of upper IC layer 102A, first lower IC layer 102B, and/or second lower IC layer 102C may be formed using a plurality of well regions and a plurality of doped isolation regions, possibly separated by shallow trench isolation (STIs) structures. In some embodiments, one or more such well regions may include doped source and/or drain regions separated by a channel region. Such circuit structures are generally not shown in FIGS. 5A, 6A, 7A, and 8A to simplify those figures.

FIGS. 5B, 6B, 7B, and 8B depict plan views for the cross-sectional views of FIGS. 5A, 6A, 7A, and 8A, respectively. Further, each of FIGS. 5B, 6B, 7B, and 8B illustrate a corresponding combination of a dielectric structure and a configuration of conductive structures providing a reference voltage (e.g., ground) connection for the photodetectors (e.g., photosensitive region 506) and/or a floating diffusion (FD) connection for transfer transistors 508.

In each of pixel cell group 105A of FIGS. 5A and 5B, pixel cell group 105B of FIGS. 6A and 6B, pixel cell group 105C of FIGS. 7A and 7B, and pixel cell group 105D of FIGS. 8A and 8B, dielectric structure 501 may extend from a lower (e.g., first or frontside) surface to an opposing upper (e.g., second or backside) surface, as shown in the cross-sectional views of FIGS. 5A, 6A, 7A, and 8A. In the plan views of FIGS. 5B, 6B, 7B, and 8B, dielectric structure 501 at least partially laterally surrounds each pixel cell 104, including around a lateral perimeter of pixel cell group 105A, 105B, 105C, and 105D. In addition, dielectric structure 501 may include a plurality of first segments 530 (or “fingers”), each of which may extend from the portion of dielectric structure 501 at the perimeter of pixel cell group 105A, 105B, 105C, and 105D toward, but not extending into, a central region of the pixel cell group (e.g., at a common corner of each pixel cell 104), thereby leaving a first “gap” 540 in dielectric structure 501.

Further, while dielectric structure 501 of pixel cell groups 105A and 105B of FIGS. 5A, 5B, 6A, and 6B is contiguous at the perimeter of those pixel cell groups, dielectric structure 501 of pixel cell groups 105C and 105D of FIGS. 7A, 7B, 8A, and 8B may instead incorporate a second gap 542 at an opposing corner of each pixel cell 104 opposite the central region or common corner of pixel cell group 105C and 105D. For example, as shown in FIGS. 7B and 8B, dielectric structure 501 may include a plurality of second segments 532 extending along the perimeter (e.g., along one side) of pixel cell group 105C and 105D, and having a first end located external to a corner region of pixel cell group 105C and 105D, and a second end located external to an adjacent corner region of pixel cell group 105C and 105D. Accordingly, in some embodiments, second segments 532 may define second gaps 542, where each second gap 542 is located at a corresponding corner region of pixel cell group 105C and 105D.

In some embodiments, first gap 540 and second gaps 542 described above may serve as access points where conductive structures may be placed to provide an additional amount of room within each pixel cell 104 for photosensitive regions 506 to capture light. For example, as depicted in FIG. 5B, a floating diffusion (FD) connection may be located at first gap 540 at the central region of pixel cell group 105A (e.g., in dielectric layer 504 over substrate 502 of upper IC layer 102A). Further, transfer transistor 508 of each pixel cell 104 may be located near the central region, or shared corner, of pixel cell group 105A, near the FD connection. Further, in some embodiments, transfer transistors 508 (e.g., the gate structure for transfer transistors 508) may be triangular in the plan view (e.g., to increase the area available for photosensitive regions 506 of pixel cell group 105A), although other shapes for the gate structure are also possible. In such embodiments, the FD connection may be shared among transfer transistors 508 (e.g., on a time-division basis).

Further, in some embodiments, as illustrated in FIG. 5B, a ground (GND) connection for each photosensitive region 506, and hence each photodetector of pixel cell group 105A, may be located near an opposing corner of each pixel cell 104 opposite the common corner in the central region of pixel cell group 105A (e.g., to maximize the area available for photosensitive regions 106). As with the FD connection, GND connections may be located in dielectric layer 504 over substrate 502 of upper IC layer 102A.

In FIGS. 6A and 6B, dielectric structure 501 is depicted as being similar to that of FIGS. 5A and 5B (e.g., having a first gap 540, but no second gaps 542). However, as shown in FIG. 6B, a GND connection, shared among pixel cells 104, may be provided at the central region of pixel cell group 105A (e.g., in dielectric layer 504 over substrate 502 of upper IC layer 102A, to be shared by the photodetector of each pixel cell 104). Further, an FD connection for each corresponding transfer transistor 508 may be located near an opposing corner of each pixel cell 104 opposite the common corner in the central region of pixel cell group 105A (e.g., in dielectric layer 504 over substrate 502 of upper IC layer 102A). Accordingly, each transfer transistor 508 may be located in a corner of its corresponding pixel cell 104 opposite the central region of pixel cell group 105B. Further, in some embodiments, in the plan view, each transfer transistor 508 may have a shape modified from the triangular shape of FIG. 5B to allow room for the FD connection in the associated pixel cell 104.

While embodiments of FIGS. 5A, 5B, 6A, and 6B do not include second gaps 542, FIGS. 7A, 7B, 8A, and 8B depict the presence of second gaps 542, as described above, in addition to first gaps 540 at the central region of pixel cell groups 105C and 105D. For example, pixel cell group 105C of FIGS. 7A and 7B and pixel cell group 105D of FIGS. 8A and 8B each include a second gap 542 at each of the corners of the pixel cell group (e.g., at the opposing corner of each pixel cell 104 opposite the common corner in the central region of pixel cell group 105C). Consequently, second gaps 542 may host conductive structures, thus potentially creating more area within each pixel cell 104 for associated photosensitive region 506.

For example, as shown in FIG. 7B, each pixel cell 104 of pixel cell group 105 may include a GND connection for each corresponding photodetector in the associated second gap 542 in dielectric structure 501 (e.g., in dielectric layer 504 over substrate 502 of upper IC layer 102A). A shared FD connection may also be located in first gap 540 of dielectric structure 501 in the central region of pixel cell group 105C, in a manner similar to that of FIG. 5B of pixel cell group 105A.

In other embodiments, as depicted in FIG. 8B, a shared GND connection may be located at first gap 540 of dielectric structure 501 in the central region of pixel cell group 105D, similar to the configuration shown in FIG. 6B. Further, dielectric structure 501 of pixel cell group 105D may include a second gap 542 at each corner thereof (e.g., the opposing corner of each pixel cell 104 opposite the shared corner), in a manner similar to that shown in FIG. 7B. Consequently, an FD connection of transfer transistor 508 of each pixel cell 104 may be located in each such second gap 542 of dielectric structure 501. Consequently, as was the case in FIG. 6B, each transfer transistor 508 may be located in a corner of its corresponding pixel cell 104 opposite the central region of pixel cell group 105B. However, with the presence of second gap 542, in which the FD connection is located, each transfer transistor 508 may maintain the triangular shape shown in FIG. 7B, in some embodiments.

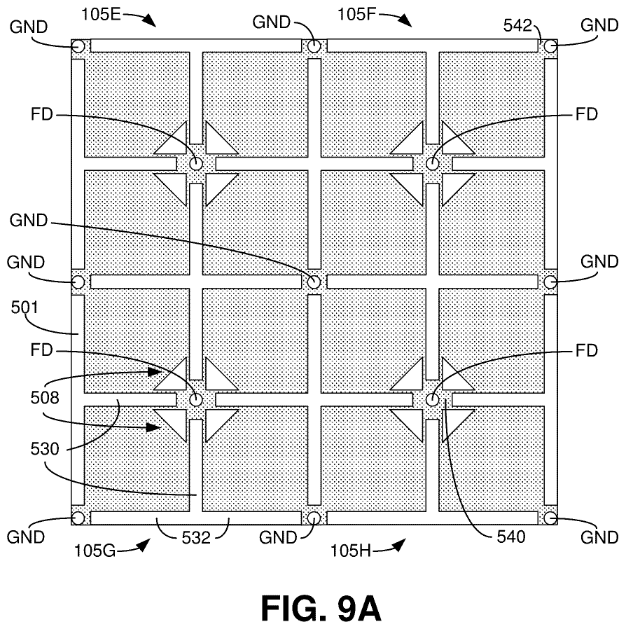

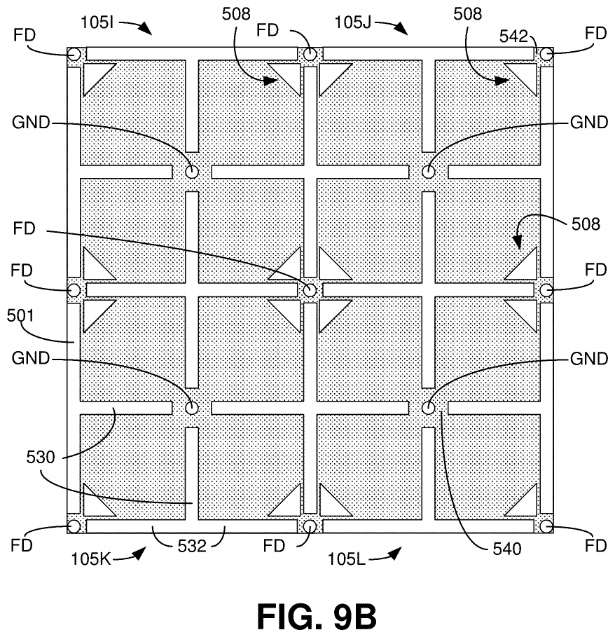

FIGS. 9A and 9B illustrate plan views of some embodiments of multiple cell groups of a multi-layer CIS IC device employing a frontside-based isolation structure, according to the present disclosure. For example, FIG. 9A depicts four pixel cell groups 105E, 105F, 105G, and 105H, each having a similar dielectric structure 501, as well as FD and GND connections, as those shown in pixel cell group 105C of FIGS. 7A and 7B. In some embodiments, perimeter portions of dielectric structures 501 of pixel cell groups 105E, 105F, 105G, and 105H, as well as their various second gaps 542 and associated GND connections, as discussed above, may be combined or shared among the pixel cell groups. Similarly, FIG. 9B depicts four pixel cell groups 105I, 105J, 105K, and 105L, each having a similar dielectric structure 501, as well as FD and GND connections, as those shown in pixel cell group 105D of FIGS. 8A and 8B. In some embodiments, perimeter portions of dielectric structures 501 of pixel cell groups 105I, 105J, 105K, and 105L, as well as their various second gaps 542 and corresponding FD connections, as discussed above, may be combined or shared among the pixel cell groups.

In yet other embodiments, pixel cell group 105A of FIGS. 5A and 5B, as well as pixel cell group 105B of FIGS. 6A and 6B, may also provide a similar multiple pixel cell group arrangement, in which perimeter portions of dielectric structures 501 may be shared between pixel cell groups, but without second gaps 542 or the collocated conductive connections discussed above in conjunction with FIGS. 9A and 9B.

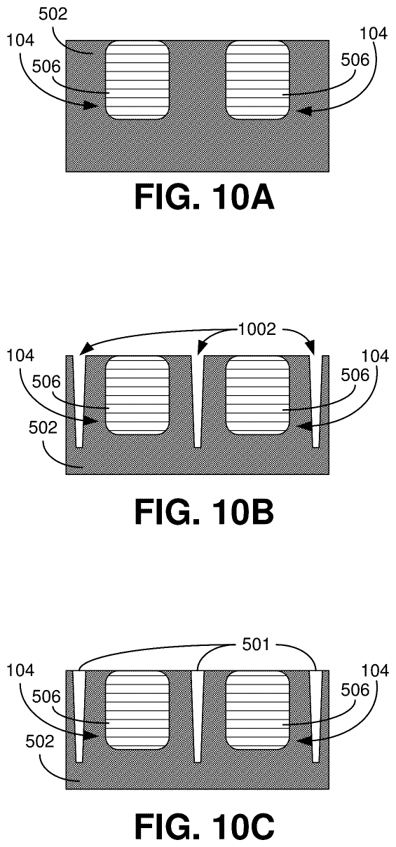

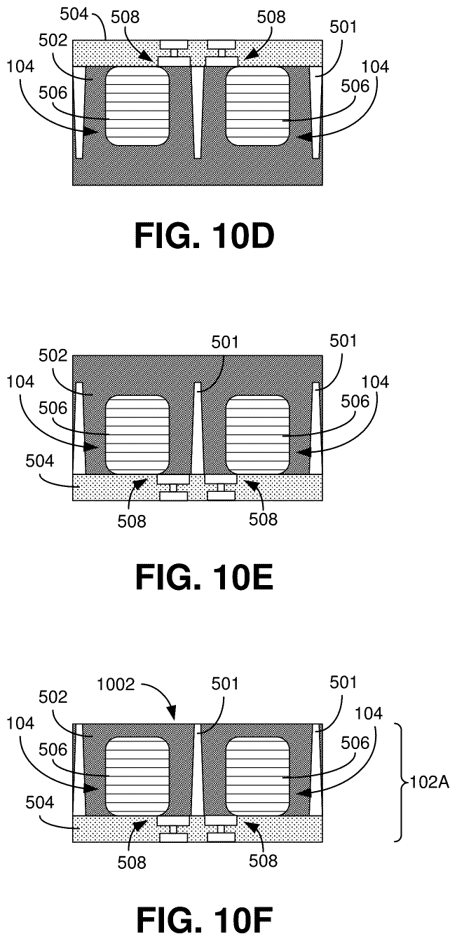

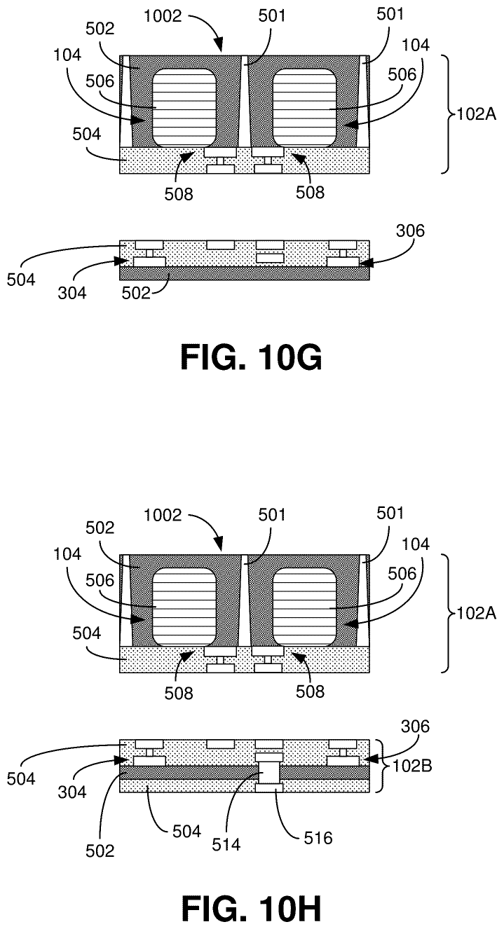

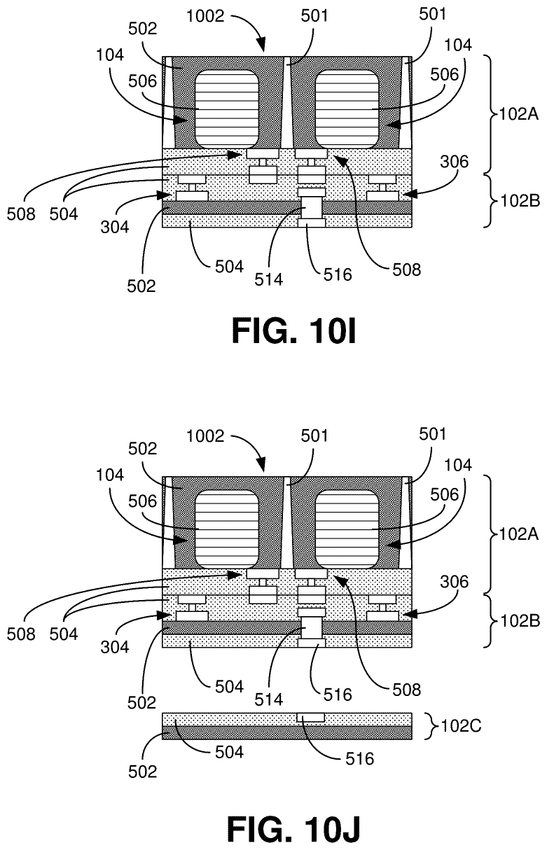

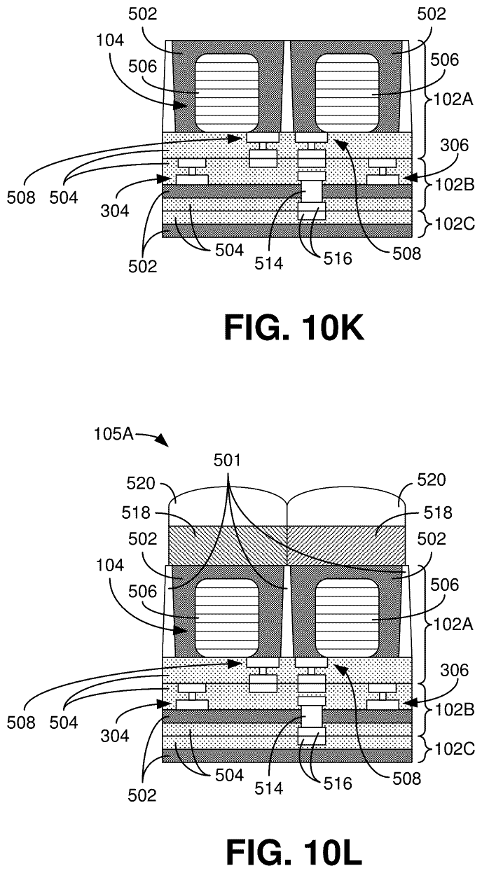

FIGS. 10A through 10L illustrate cross-sectional side views of some embodiments of a CIS multi-die IC device employing a frontside-based isolation structure at various stages of manufacture, according to the present disclosure. While FIGS. 10A through 10L are particularly associated with pixel cell group 105A of FIGS. 5A and 5B, other pixel cell group embodiments may employ the same or similar stages of manufacture described below.

Although FIGS. 10A through 10L are described as a series of acts, it will be appreciated that these acts are not limiting in that the order of the acts can be altered in other embodiments, and the methods disclosed are also applicable to other structures. In other embodiments, some acts that are illustrated and/or described may be omitted in whole or in part.

FIG. 10A illustrates the forming (e.g., implantation or doping) of a plurality of photosensitive regions 506 formed at a first surface of a substrate 502. Substrate 502 may be a semiconductor substrate (e.g., a silicon (Si) substrate) that will serve as a basis for upper IC layer 102A of pixel cell group 105A of CIS IC device 100. Each photosensitive region 506 may include a light-absorption region that, in combination with substrate 502, forms a photodetector (e.g., photodiode) that is sensitive to a light wavelength band. In some embodiments, semiconductor substrate 502 may be p-doped silicon, and photosensitive regions 506 may be portions of substrate 502 that have been implanted or doped with ions to create an n-doped region. In some embodiments, the photodiodes generated by the formation of photosensitive regions 506 may be PN photodiodes (e.g., “pinned” photodiodes) that are sensitive to photons of visible light. In addition, other doped regions, such as an n-doped region for each transfer transistor 508 associated with each photodetector, may also be formed in substrate 502, but are not explicitly shown in FIG. 10A.

FIG. 10B illustrates the forming (e.g., etching or other removal) of at least one trench 1002 about pixel cell group 105A and associated photosensitive regions 506. In some embodiments, the location of at least one trench 1002 determines the location of at least one dielectric structure 501, as described above in connection with FIGS. 5A and 5B. In some embodiments, trench 1002 is formed by way of the same side (e.g., the frontside) or surface by which photosensitive regions 506 are formed (e.g., opposite the side (e.g., the backside) or surface by which light will ultimately be received by CIS IC device 100). Also, in some embodiments, trench 1002 may extend partway into substrate 502, as depicted in FIG. 10B. In other embodiments, trench 1002 may extend completely through substrate 502 (e.g., in cases in which a carrier or other structure is attached to the opposing side of substrate 502). Also, in some embodiments, trench 1002 may be wider at the frontside of substrate 502 and narrower at the backside of substrate 502.

FIG. 10C illustrates the forming (e.g., deposition of filling) of dielectric material (e.g., a silicon oxide (SiOₓ), such as silicon dioxide (SiO₂), or another dielectric material) to form dielectric structure 501, as described above in conjunction with FIGS. 5A, 5B, 6A, 6B, 7A, 7B, 8A, and 8B. In some embodiments, dielectric structure 501 may have the structure or characteristics of a deep trench isolation (DTI) structure. Further, in some embodiments, after forming dielectric structure 501, a planarization processing operation (e.g., using chemical-mechanical planarization (CMP)) may be performed on the frontside surface of FIG. 10C.

FIG. 10D illustrates the forming (e.g., deposition, photolithography, etching, and/or the like) of gate structures of transfer transistor 508 coupled with the photodetector associated with each pixel cell 104 within a dielectric layer 504 over substrate 502 (e.g., at the frontside surface thereof). As shown, additional conductive elements (source-drain connections, conductive layers, interconnecting conductive vias, and so on) associated with transfer transistors 508 may also be formed in conjunction with dielectric layer 504. As with other dielectric layers discussed herein, dielectric layer 504 may include a silicon oxide (SiOₓ), such as silicon dioxide (SiO₂), and/or one or more other dielectric materials.

FIG. 10E illustrates the reorientation (e.g., flipping) of substrate 502, dielectric layer 504, and associated elements described above to provide access to the backside of substrate 502.

FIG. 10F illustrates the removal (e.g., blanket etching) of a portion of substrate 502 at the backside thereof to facilitate the extension of dielectric structure 501 through substrate 502. In some embodiments in which trench 1002 was initially formed through substrate 502 (e.g., in the case described above in which a carrier or similar structure is employed to stabilize substrate 502), the removal operation of FIG. 10F may not be necessary.

FIG. 10G illustrates the provision of a second substrate 502 (e.g., a silicon substrate) and the deposition of various electrical elements (e.g., source follower transistor 304 and/or row select transistor 306 (e.g., in per-pixel circuit 308 of FIG. 3), including various conductive elements, doped regions, and so on) within substrate 502 and a first dielectric layer 504 that is formed over second substrate 502.

FIG. 10H illustrates the forming (e.g., deposition) of a second dielectric layer 504 on a surface of second substrate 502 opposite that of first dielectric layer 504 to form first lower IC layer 102B. In some embodiments, one or more through-substrate vias (TSVs) 514 may be formed through substrate 502 of first lower IC layer 102B and partially into one or both of first and second dielectric layers 504. Also, a conductive structure 516 may be formed at a surface of second dielectric layer 504 to facilitate a connection from first dielectric layer 504, through second substrate 502, to conductive structure 516.

FIG. 10I illustrates the joining (e.g., bonding) of first lower IC layer 102B to the frontside of upper IC layer 102A by way of dielectric layers 504 and corresponding conductive structures. In some embodiments, the bonding may include direct bond interconnect (DBI) or other methods or operations of bonding together dielectric layers and associated conductive structures. For example, such bonding may combine a dielectric bond of first and second dielectric layers 504 by way of dielectric-to-dielectric bonding (e.g., at room temperature). Thereafter, in some embodiments, heat may be applied to compress the first and second pluralities of aligned conductive structures shown in FIG. 10I together to create direct connections therebetween. In some embodiments, such internal compression is possible by way of a coefficient of thermal expansion (CTE) of the first and second pluralities of conductive structures being greater than a CTE of first and second dielectric layers 504.

FIG. 10J illustrates the fabrication of second lower IC layer 102C that may include ASIC circuit 320 (e.g., as shown in FIG. 3) and/or other circuitry. Second lower IC layer 402C may include a third substrate 502 and fourth (upper) dielectric layer 504. In some embodiments, dielectric layer 504 may include a conductive structure 516 that will align with corresponding conductive structure 516 of first lower IC layer 102B.

FIG. 10K illustrates the joining (e.g., bonding) of first lower IC layer 102B and second lower IC layer 102C by way of third and fourth dielectric layers 504 and corresponding conductive structure 516 (e.g., to facilitate the creation of one or more electrical connections between first lower IC layer 102B and second lower IC layer 102C. In some embodiments, the bonding may include DBI or other bonding methods, as described above.

FIG. 10L illustrates the forming (e.g., deposition and/or bonding) of a filter 518 (e.g., color filters) and a lens 520 (e.g., microlens) for each associated pixel cell 104 over an upper (e.g., backside) surface of substrate 502 of upper IC layer 102A. As described above, filters 518 may filter out or allow passage of particular wavelength bands of light, while lenses 520 may focus or otherwise direct received light toward its corresponding pixel cell 104.

While FIGS. 10A through 10L indicate a particular order in which CIS IC device 100 may be fabricated, other orders of operation are possible in other embodiments. For example, in some embodiments, the order of bonding of the IC layers 102A-102C may be performed in a different order, such as first bonding together first lower IC layer 102B and second lower IC layer 102C prior to bonding with upper IC layer 102A.

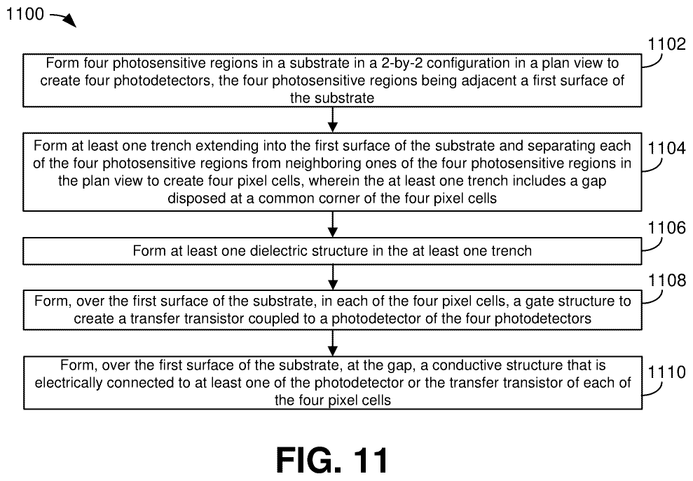

FIG. 11 illustrates a methodology 1100 of forming a CIS multi-die IC device (e.g., CIS IC device 100, including pixel cell groups 105A, 105B, 105C, and 105D) in accordance with some embodiments. Although this method and other methods illustrated and/or described herein are illustrated as a series of acts or events, it will be appreciated that the present disclosure is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

At Act 1102, for example, four photosensitive regions (e.g., photosensitive regions 506 of FIG. 10A) are formed in a substrate (e.g., substrate 502 of FIG. 10A) in a 2-by-2 configuration in a plan view to create four photodetectors (e.g., photodetector 202 of FIG. 2A or photodiode 302 of FIGS. 2B and 3) adjacent a first surface (e.g., a frontside surface) of the substrate. FIG. 10A illustrates a cross-sectional view of some embodiments corresponding to Act 1102.

At Act 1104, at least one trench (e.g., trench 1002 of FIG. 10B) is formed that extends into the first surface of the substrate and separates each of the four photosensitive regions from neighboring ones of the four photosensitive regions in the plan view to create four pixel cells (e.g., pixel cells 104 of FIGS. 5A, 6A, 7A, and 8A), wherein the at least one trench includes a gap (e.g., first gap 540 where the FD connection is located in a central region) disposed at a common corner of the four pixel cells. FIG. 10B illustrates a cross-sectional view of some embodiments corresponding to Act 1104.

At Act 1106, at least one dielectric structure (e.g., dielectric structure 501 of FIGS. 5A, 5B, 6A, 6B, 7A, 7B, 8A, and 8B) is formed in the at least one trench. FIG. 10C illustrates a cross-sectional view of some embodiments corresponding to Act 1106.

At Act 1108, a gate structure is formed over the first surface of the substrate in each of the four pixel cells to create a transfer transistor (e.g., transfer transistor 204 of FIGS. 2A, 2B, and 3; and transfer transistor 508 of FIGS. 5A, 5B, 6A, 6B, 7A, 7B, 8A, and 8B) coupled to a photodetector of the four photodetectors. At Act 1110, a conductive structure (e.g., FD connection of FIGS. 5B and 7B; and GND connection of FIGS. 6B and 8B) is formed at the gap over the first surface of the substrate that is electrically connected to at least one of the photodetector or the transfer transistor of each of the four pixel cells. FIG. 10D illustrates a cross-sectional view of some embodiments corresponding to Acts 1108 and 1110.

Some embodiments relate to an IC device. The IC device includes an IC layer including a plurality of pixel cell groups, each of the plurality of pixel cell groups including: a plurality of pixel cells arranged in a 2-by-2 configuration in a plan view, each of the plurality of pixel cells including: a photodetector in a substrate of the IC layer; and a transfer transistor electrically coupled to the photodetector and configured to transfer electrical charge collected at the photodetector across a first surface of the substrate; and at least one dielectric structure extending from the first surface of the substrate to a second surface of the substrate and separating each of the plurality of pixel cells from neighboring ones of the plurality of pixel cells, wherein the at least one dielectric structure includes a first gap disposed at a common corner of the plurality of pixel cells, wherein a first conductive structure is electrically connected to at least one of the photodetector or the transfer transistor of each of the plurality of pixel cells and is disposed in the first gap over the first surface of the substrate.

Some embodiments relate to another IC device. The IC device includes an IC layer including a plurality of pixel cell groups, each of the plurality of pixel cell groups including: a plurality of pixel cells arranged in a 2-by-2 configuration in a plan view, each of the plurality of pixel cells including: a photodetector in a substrate of the IC layer; and a transfer transistor electrically coupled to the photodetector and configured to transfer electrical charge collected at the photodetector across a first surface of the substrate; and at least one dielectric structure extending from the first surface of the substrate to a second surface of the substrate and separating each of the plurality of pixel cells from neighboring ones of the plurality of pixel cells in the plan view, wherein the at least one dielectric structure includes a plurality of first segments, each of the plurality of first segments having a first end and a second end, the first end being located at a perimeter of the 2-by-2 configuration, and the second end being located external to a central region of the 2-by-2 configuration, wherein a first conductive structure is electrically connected to at least one of the photodetector or the transfer transistor of each of the plurality of pixel cells and is disposed in the central region over the first surface of the substrate.

Some embodiments relate to a method. The method includes: forming four photosensitive regions in a substrate in a 2-by-2 configuration in a plan view to create four photodetectors, the four photosensitive regions being adjacent a first surface of the substrate; forming at least one trench extending into the first surface of the substrate and separating each of the four photosensitive regions from neighboring ones of the four photosensitive regions in the plan view to create four pixel cells, wherein the at least one trench includes a first gap disposed at a common corner of the four pixel cells; forming at least one dielectric structure in the at least one trench; forming, over the first surface of the substrate, in each of the four pixel cells, a gate structure to create a transfer transistor coupled to a photodetector of the four photodetectors; and forming, over the first surface of the substrate, at the first gap, a first conductive structure that is electrically connected to at least one of the photodetector or the transfer transistor of each of the four pixel cells.

It will be appreciated that in this written description, as well as in the claims below, the terms “first”, “second”, “third” etc. are merely generic identifiers used for ease of description to distinguish between different elements of a figure or a series of figures. In and of themselves, these terms do not imply any temporal ordering or structural proximity for these elements, and are not intended to be descriptive of corresponding elements in different illustrated embodiments and/or un-illustrated embodiments. For example, “a first dielectric layer” described in connection with a first figure may not necessarily correspond to a “first dielectric layer” described in connection with another figure, and may not necessarily correspond to a “first dielectric layer” in an un-illustrated embodiment.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit (IC) device, comprising:
an IC layer comprising a plurality of pixel cell groups, each of the plurality of pixel cell groups comprising:
a plurality of pixel cells arranged in a 2-by-2 configuration in a plan view, each of the plurality of pixel cells comprising:
a photodetector in a substrate of the IC layer; and
a transfer transistor electrically coupled to the photodetector and configured to transfer electrical charge collected at the photodetector across a first surface of the substrate; and
at least one dielectric structure extending from the first surface of the substrate to a second surface of the substrate and separating each of the plurality of pixel cells from neighboring ones of the plurality of pixel cells, wherein the at least one dielectric structure includes a first gap disposed at a common corner of the plurality of pixel cells, wherein a first conductive structure is electrically connected to at least one of the photodetector or the transfer transistor of each of the plurality of pixel cells and is disposed in the first gap over the first surface of the substrate.

2. The IC device of claim 1, wherein the transfer transistor of each of the plurality of pixel cells is disposed proximate the common corner of the plurality of pixel cells.

3. The IC device of claim 1, wherein a gate structure of the transfer transistor of each of the plurality of pixel cells comprises a triangular shape in the plan view.

4. The IC device of claim 1, wherein:
the first conductive structure provides a ground connection for the photodetector of each pixel cell of the plurality of pixel cells; and
each pixel cell of the plurality of pixel cells comprises a second conductive structure over the first surface of the substrate, the second conductive structure providing a floating diffusion connection for the transfer transistor of the pixel cell, the second conductive structure being disposed proximate an opposing corner of the pixel cell opposite the common corner.

5. The IC device of claim 1, wherein:
the first conductive structure provides a floating diffusion connection for the transfer transistor of each pixel cell of the plurality of pixel cells; and
each pixel cell of the plurality of pixel cells comprises a second conductive structure over the first surface of the substrate, the second conductive structure providing a ground connection for the photodetector of the pixel cell, the second conductive structure being disposed proximate an opposing corner of the pixel cell opposite the common corner.

6. The IC device of claim 1, wherein the at least one dielectric structure further comprises a plurality of second gaps, each of the plurality of second gaps being disposed at an opposing corner of a corresponding one of the plurality of pixel cells opposite the common corner.

7. The IC device of claim 6, wherein:
the first conductive structure provides a ground connection for the photodetector of each pixel cell of the plurality of pixel cells; and
each pixel cell of the plurality of pixel cells comprises a second conductive structure over the first surface of the substrate, the second conductive structure providing a floating diffusion connection for the transfer transistor of the pixel cell, the second conductive structure being disposed in the second gap associated with the pixel cell.

8. The IC device of claim 6, wherein:
the first conductive structure provides a floating diffusion connection for the transfer transistor of each pixel cell of the plurality of pixel cells; and
each pixel cell of the plurality of pixel cells comprises a second conductive structure over the first surface of the substrate, the second conductive structure providing a ground connection for the photodetector of the pixel cell, the second conductive structure being disposed in the second gap associated with the pixel cell.

9. The IC device of claim 6, wherein:
one of the plurality of pixel cell groups and another one of the plurality of pixel cell groups are adjacent each other; and
the one of the plurality of pixel cell groups and the other one of the plurality of pixel cell groups share at least one of the second gaps of the at least one dielectric structure.

10. An integrated circuit (IC) device, comprising:
an IC layer comprising a plurality of pixel cell groups, each of the plurality of pixel cell groups comprising:
a plurality of pixel cells arranged in a 2-by-2 configuration in a plan view, each of the plurality of pixel cells comprising:
a photodetector in a substrate of the IC layer; and
a transfer transistor electrically coupled to the photodetector and configured to transfer electrical charge collected at the photodetector across a first surface of the substrate; and
at least one dielectric structure extending from the first surface of the substrate to a second surface of the substrate and separating each of the plurality of pixel cells from neighboring ones of the plurality of pixel cells in the plan view, wherein the at least one dielectric structure includes a plurality of first segments, each of the plurality of first segments having a first end and a second end, the first end being located at a perimeter of the 2-by-2 configuration, and the second end being located external to a central region of the 2-by-2 configuration, wherein a first conductive structure is electrically connected to at least one of the photodetector or the transfer transistor of each of the plurality of pixel cells and is disposed in the central region over the first surface of the substrate.

11. The IC device of claim 10, wherein:
the first conductive structure provides a ground connection for the photodetector of each pixel cell of the plurality of pixel cells; and
each pixel cell of the plurality of pixel cells comprises a second conductive structure over the first surface of the substrate and providing a floating diffusion connection for the transfer transistor of the pixel cell, the second conductive structure being disposed proximate an opposing corner of the pixel cell opposite the central region.

12. The IC device of claim 10, wherein:
the first conductive structure provides a floating diffusion connection for the transfer transistor of each pixel cell of the plurality of pixel cells; and
each pixel cell of the plurality of pixel cells comprises a second conductive structure over the first surface of the substrate and providing a ground connection for the photodetector of the pixel cell, the second conductive structure being disposed proximate an opposing corner of the pixel cell opposite the central region.

13. The IC device of claim 10, wherein the at least one dielectric structure further comprises a plurality of second segments, each of the plurality of second segments extending along the perimeter of the 2-by-2 configuration, each of the plurality of second segments having a first end located external to one of a plurality of corner regions of the 2-by-2 configuration and a second end located external to another one of the plurality of corner regions of the 2-by-2 configuration.

14. The IC device of claim 13, wherein:
the first conductive structure provides a ground connection for the photodetector of each pixel cell of the plurality of pixel cells; and
each pixel cell of the plurality of pixel cells comprises a second conductive structure over the first surface of the substrate and providing a floating diffusion connection for the transfer transistor of the pixel cell, the second conductive structure being disposed in a corresponding one of the corner regions of the 2-by-2 configuration.

15. The IC device of claim 13, wherein:
the first conductive structure provides a floating diffusion connection for the transfer transistor of each pixel cell of the plurality of pixel cells; and
each pixel cell of the plurality of pixel cells comprises a second conductive structure over the first surface of the substrate and providing a ground connection for the photodetector of the pixel cell, the second conductive structure being disposed in a corresponding one of the corner regions of the 2-by-2 configuration.

16. A method, comprising:
forming four photosensitive regions in a substrate in a 2-by-2 configuration in a plan view to create four photodetectors, the four photosensitive regions being adjacent a first surface of the substrate;
forming at least one trench extending into the first surface of the substrate and separating each of the four photosensitive regions from neighboring ones of the four photosensitive regions in the plan view to create four pixel cells, wherein the at least one trench includes a first gap disposed at a common corner of the four pixel cells;
forming at least one dielectric structure in the at least one trench;
forming, over the first surface of the substrate, in each of the four pixel cells, a gate structure to create a transfer transistor coupled to a photodetector of the four photodetectors; and
forming, over the first surface of the substrate, at the first gap, a first conductive structure that is electrically connected to at least one of the photodetector or the transfer transistor of each of the four pixel cells.

17. The method of claim 16, further comprising:
forming, over the first surface of the substrate, proximate an opposing corner of each of the four pixel cells opposite the common corner, a second conductive structure, wherein
the first conductive structure provides a ground connection for the photodetector of each pixel cell of the four pixel cells; and
each of the second conductive structures provides a floating diffusion connection for the transfer transistor of the corresponding pixel cell.

18. The method of claim 16, further comprising:
forming, over the first surface of the substrate, proximate an opposing corner of each of the four pixel cells opposite the common corner, a second conductive structure, wherein
the first conductive structure provides a floating diffusion connection for the transfer transistor of each pixel cell of the four pixel cells; and
each of the second conductive structures provides a ground connection for the photodetector of the corresponding pixel cell.

19. The method of claim 16, wherein the at least one trench further includes four second gaps, each of the four second gaps being disposed at an opposing corner of a corresponding one of the four pixel cells opposite the common corner, the method further comprising:
forming, over the first surface of the substrate in each of the four second gaps, a second conductive structure, wherein
the first conductive structure provides a ground connection for the photodetector of each pixel cell of the four pixel cells; and
each of the second conductive structures provides a floating diffusion connection for the transfer transistor of the corresponding pixel cell.

20. The method of claim 16, wherein the at least one trench further includes four second gaps, each of the four second gaps being disposed at an opposing corner of a corresponding one of the four pixel cells opposite the common corner, the method further comprising:
forming, over the first surface of the substrate in each of the four second gaps, a second conductive structure, wherein
the first conductive structure provides a floating diffusion connection for the transfer transistor of each pixel cell of the four pixel cells; and
each of the second conductive structures provides a ground connection for the photodetector of the corresponding pixel cell.
